(19) United States
(12) Patent Application Publication
(10) Pub. No.: US 2024/0105548 A1
(43) Pub. Date: Mar. 28, 2024

(54) PRINTED CIRCUIT BOARD ASSEMBLY AND METHOD OF MANUFACTURING A PRINTED CIRCUIT BOARD ASSEMBLY

(71) Applicant: Rolls-Royce Deutschland Ltd & Co KG, Blankenfelde-Mahlow (DE)

(72) Inventor: Uwe WALTRICH, Forchheim (DE)

(21) Appl. No.: 18/372,085

(22) Filed: Sep. 23, 2023

(30) Foreign Application Priority Data
Sep. 23, 2022 (DE) 10 2022 124 513.6

(51) Int. Cl. H01L 23/40; H01L 23/00; H01L 25/11; H05K 1/18; H05K 3/28

(52) U.S. Cl. CPC H01L 23/4006; H01L 24/20; H01L 25/115; H05K 1/181; H05K 3/284; H01L 23/49838; H01L 2224/214

(57) ABSTRACT

A circuit board arrangement includes a circuit board having an upper side and an underside, and an electrical module, having an upper side and an underside, that is arranged with its upper side on the underside of the circuit board. The circuit board arrangement also includes a heat sink, means for providing a pressure, with which the underside of the electrical module is pressed against the heat sink, and a heat-conducting material that is arranged between the underside of the electrical module and the heat sink. The at least one electrical module is embedded in an encapsulating material that terminates with the underside of the electrical module without covering the underside of the electrical module. The encapsulating material is provided and configured to press the heat-conducting material against the heat sink in a region adjacent to the electrical module.

This application claims the benefit of German Patent Application No. DE 10 2022 124 513.6, filed on Sep. 23, 2022, which is hereby incorporated by reference in its entirety.

### BACKGROUND

The present embodiments relate to a circuit board arrangement, and to a method for producing a circuit board arrangement.

The prior art includes the practice of cooling circuit board-based power electronics assemblies by pressing the circuit board-based power electronics assemblies against a heat sink by screwed joints. The components to be cooled are typically configured as surface-mounted (SMD) components (e.g., “surface-mounted device”) or as through-hole assemblies (e.g., “through-hole technology” (THT)) and are seated on the underside of a circuit board. The components to be cooled include an embedded semiconductor component and are also referred to as prepackage modules or, in the terminology used here, as electrical modules.

Depending on the performance class, a large number of prepackage modules to be cooled is arranged on the underside of the circuit board and pressed against a heat sink for the purpose of cooling. In this case, any gap between the electrical module to be cooled and the heat sink leads to impairment of the thermal connection of the electrical module to the heat sink. A gap between a module to be cooled and the heat sink may therefore be minimized. In the case of a plurality of electrical modules that are to be cooled, there may be gaps with different gap dimensions with respect to the heat sink that are to be compensated. Further, tolerances in the gap dimensions result from a thickness tolerance of the circuit board, local thermal deflections of the circuit board, and unevenness in the heat sink surface.

One known practice for compensating these height tolerances is to use heat-conducting materials. In power electronics, paste systems or films are used, and these are applied to the cooling surface and compensate for minimal gaps and roughness of up to 100 μm. However, effective heat transfer to the heat sink is only present in the region of the electrical modules since these are pressed against the heat sink, and the thermal resistance decreases with increased mechanical pressure.

### SUMMARY AND DESCRIPTION

The scope of the present invention is defined solely by the appended claims and is not affected to any degree by the statements within this summary.

The present embodiments may obviate one or more of the drawbacks or limitations in the related art. For example, a circuit board arrangement that provides an improved thermal connection of an electrical module to a heat sink is provided, and a method for producing such a circuit board arrangement is provided.

In a first aspect, the present embodiments consider a circuit board arrangement that has a circuit board having an upper side and an underside, at least one electrical module arranged on the underside of the circuit board, a heat sink, means for providing a pressure, with which the underside of the electrical module is pressed against the heat sink, and a heat-conducting material. The heat-conducting material is arranged between the underside of the electrical module and the heat sink.

The at least one electrical module is embedded in an encapsulating material that terminates with the underside of the electrical module without covering the underside. The encapsulating material is provided and configured to press the heat-conducting material against the heat sink in the region adjacent to the at least one electrical module.

The solution according to the present embodiments is based on the concept of improving the thermal coupling of an electrical module to a heat sink by virtue of the fact that an encapsulating material, into which the electrical module is cast, additionally presses the heat-conducting film against the heat sink at the sides of the electrical module, thus providing that the thermal transition to the heat sink takes place over a larger heat sink surface area.

The solution according to the present embodiments is based on the insight that the thermal transition to the heat sink is heavily dependent on the contact pressure on the heat sink. In conventional circuit board arrangements, the contact pressure is high only in the region of the electrical modules to be cooled, which are pressed against the heat sink. Next to the electrical modules, the heat-conducting material only rests against the heat sink surface, without contact pressure, and therefore heat transfer to the heat sink is low in these regions. Embedding the electrical module or a plurality of electrical modules in an encapsulating material enables the heat-conducting material to be pressed against the heat sink surface in a region adjacent to the electrical module and between the individual electrical modules as well. In this way, the thermal transition to the heat sink is improved overall.

The solution according to the present embodiments thus achieves an improvement in the heat distribution over the surface of the heat sink and thus improved cooling of the electrical modules. This makes it possible to use smaller cooling systems.

For the purposes of the present embodiments, the side of the circuit board on which an electrical module to be cooled is arranged is always referred to as the underside of the circuit board, irrespective of the actual orientation of the circuit board and the electrical module in space.

If the circuit board arrangement has a plurality of electrical modules, these may be jointly embedded in an encapsulating material. The encapsulating material presses the heat-conducting material against the heat sink in the region between the electrical modules.

In refinements of the present embodiments, the encapsulating material extends as far as the underside of the circuit board, at least in some section or sections, providing that the open space between the heat-conducting material and the underside of the circuit board is completely or at least partially filled with the encapsulating material. As a result, improved cooling of all components of the circuit board is achieved by full-area connection of the circuit board to the heat sink.

In addition, this embodiment allows partial electrical insulation of critical regions on the underside of the circuit board or in the region between the electrical module and the circuit board. In this context, the arrangement of the electrical modules on the circuit board or on a carrier board is accomplished by a soldering process, in which mutually associated solder pads on the electrical module and on the circuit board are connected to one another by a solder layer. Owing to the principle involved, an air gap arises between the electrical module and the circuit board during this process. In conventional practice, an insulating material is introduced into this air gap in an underfill process, protecting, for example, against partial discharges and enabling compliance with clearances and creepage distances. On the production side, however, the application of an underfill material is challenging. The material is applied next to the electrical module and then creeps into the gap on account of the capillary effect. In this process, the quality of the underfill layer as regards the required freedom from bubbles depends on numerous factors, such as the cleanliness of the gap, the gap height, the gap geometry, and the surfaces used.

The solution according to the present embodiments makes it possible to avoid an underfill process and instead to fill the gap between the upper side of the electrical module and the underside of the circuit board with the encapsulating material. Thus, one embodiment provides that the electrical module has electrical solder pads formed on its upper side, which are each in contact via a solder layer with an associated electrical solder pad of the circuit board. In the region adjacent to the solder pads, the encapsulating material extends also in the gap between the underside of the circuit board and the upper side of the electrical module. An underfill material is thus replaced by the encapsulating material. As a result, the risk of bubble formation in the gap between the electrical module and the circuit board is reduced since the encapsulating material exhibits significantly better gap penetration in each of the embodiments and may also be injected at high pressure, for example, by transfer molding, as will be explained below.

Another embodiment provides that the encapsulating material also surrounds and electrically insulates those regions on the underside of the circuit board in which the circuit board forms vias. In this respect, it is observed, as regards the background, that the electrical contacts on the circuit board are typically supplied with voltage via plated-through holes or vias in the circuit board. Contact surfaces of the circuit board provided with such vias are to be electrically insulated. When an underfill material is used, the underfill material may not be applied exactly to the circuit board and thus to the surfaces to be insulated owing to its crosslinking properties. The result is that further process acts with an additional material are to be carried out (e.g., using a “dam & fill” process) in order to insulate the vias. The additional material forms a boundary layer with respect to the underfill material.

The solution according to the present embodiments avoids these problems in that the encapsulating material also serves to insulate those regions on the underside of the circuit board in which the circuit board forms vias. The encapsulating material is thus used for partial insulation of critical regions on the circuit board.

One embodiment provides that the encapsulating material has a hardness that is greater than the hardness of the heat-conducting material, enabling the encapsulating material to press the heat-conducting material against the heat sink in an effective manner. In this case, the encapsulating material may be configured as a hard encapsulating compound. Variants provide for the encapsulating material to have a Shore D hardness greater than 10.

In embodiments, the encapsulating material is a thermosetting plastic. The encapsulating material is an epoxy resin, for example. A two-component epoxy consists of a polymer resin and a curing agent that react chemically with one another. An epoxy encapsulating compound is distinguished by a high stiffness and tensile strength, a high temperature stability, and low shrinkage. The epoxy encapsulating compound also has a high dielectric strength.

Another embodiment provides that the at least one electrical module has been embedded in the encapsulating material by transfer molding or injection molding. These methods make it possible to overmold the electrical module under pressure in a defined manner, and the volume to be overmolded may be precisely defined. In this case, it is also possible for certain regions of the circuit board arrangement to be filled with encapsulating material and partially insulated, such as the gap between the electrical module and the circuit board and via regions on the circuit board.

Another embodiment provides that the heat-conducting material includes an anisotropic heat-conducting film that has an increased thermal conductivity in the plane (e.g., in the range between 200 W/mK and 1000 W/mK). In this case, the heat-conducting film is, for example, a graphite film. The use of an anisotropic heat-conducting film makes it possible to spread the heat generated locally in the electrical modules over the plane of the heat-conducting film. The heat spread in the plane may be effectively dissipated into the heat sink since the heat-conducting material is also pressed against the heat sink in the region adjacent to the electrical modules by the encapsulating material, providing that there is an effective thermal transition to the heat sink over the entire heat sink surface.

The means for providing a pressure, with which the underside of the electrical module is pressed against the heat sink, includes screws, for example, that extend from the upper side of the circuit board into the heat sink and are screwed into the heat sink. The means for providing a pressure may additionally or alternatively contain further means (e.g., a hold-down device that presses against the circuit board from above).

In embodiments, the electrical module is constructed such that the electrical module includes a ceramic circuit carrier that has an insulating ceramic layer and a metallization layer arranged on the upper side of the ceramic layer, and an electrical component that is arranged on the upper side of the metallization layer and is electrically connected thereto. The ceramic layer or a second metallization layer formed on the underside of the ceramic layer is connected to the heat sink via the heat-conducting material.

Ceramic circuit carriers serve for electrical insulation of the electrical component provided with the ceramic circuit carrier from the heat sink and at the same time for thermal connection to the heat sink.

The electrical component integrated in the electrical module may be a semiconductor component (e.g., a power semiconductor such as a power MOSFET or an IGBT component). This is, for example, a power semiconductor of an inverter or, in general, of a power converter that is provided for the operation of an electric motor.

In one embodiment, electrical contacts of the module may include at least one first via that extends from a solder pad on the upper side to the first metallization layer, and second and third vias that extend from other solder pads on the upper side to corresponding contacts on the upper side of the electrical component. This enables contact to be made with the electrical component via contacts arranged on the upper side of the electrical module.

Another embodiment provides that the at least one electrical module is arranged in a cavity of the heat sink.

In a further aspect of the present embodiments, a method for producing a circuit board arrangement is provided. The method includes arranging and electrically contacting at least one electrical module on the underside of a circuit board; inserting the circuit board with the at least one electrical module into a mold; applying a punch with a compensating film to the underside of the at least one electrical module and pressing the compensating film against the underside; closing the mold; injecting a molding compound into the mold, where the at least one electrical module is overmolded without the underside, covered with the compensating film, of the electrical module being covered with the molding compound; curing the molding compound to form an encapsulating compound; removing the circuit board with the at least one electrical module encapsulated by the encapsulating compound from the mold; and thermally coupling the at least one electrical module to a heat sink using a heat-conducting material and means for providing a pressure. In the region adjacent to the at least one electrical module, the encapsulating material presses the heat-conducting material against the heat sink.

This aspect of the present embodiments provides a robust and defined method for insulating and overmolding electrical modules and other circuit board regions.

A molding compound may be injected into the mold by transfer molding or injection molding, for example.

One embodiment provides that, during the injection of the molding compound into the mold, the at least one electrical module is overmolded such that the molding compound also closes a gap between the underside of the circuit board and the upper side of the electrical module (e.g., apart from those regions in which, as explained, electrical solder pads and solder layers are formed).

It may also be provided that, during the injection of the molding compound into the mold, the at least one electrical module is overmolded such that the molding compound also surrounds and electrically insulates those regions on the underside of the circuit board in which the circuit board forms vias.

Further variants provide for the method to be used in a panel, where a plurality of electrical modules is simultaneously overmolded in the mold.

### BRIEF DESCRIPTION OF THE DRAWINGS

FIG. 1 schematically shows an example of an embodiment of a circuit board arrangement that includes an electrical module arranged on a circuit board;

FIG. 1a shows a detail of the circuit board arrangement of FIG. 1;

FIG. 2 shows a circuit board arrangement according to FIG. 1, where additional details with regard to an electrical module are shown;

FIG. 3 shows an example of a circuit board arrangement not according to the present embodiments;

FIG. 4 schematically shows embedding of two electrical modules in an encapsulating material in a manner not according to the present embodiments, in which an underside of the electrical module is covered with the encapsulating material;

FIG. 5 shows a mold for producing a circuit board arrangement according to FIG. 1;

FIG. 6 shows an electrical module of a circuit board arrangement according to FIG. 1, where the underside of the electrical module has a vertical offset at edges with respect to the encapsulating material in which the electrical module is embedded; and

FIG. 7 shows a flow chart of one embodiment of a method for producing a circuit board arrangement according to FIG. 1.

### DETAILED DESCRIPTION

To give a better understanding of the background of the present embodiments, a circuit board arrangement not according to the present embodiments is first described with reference to FIG. 3.

FIG. 3 shows a circuit board arrangement that includes a circuit board 1 and a heat sink 3. The circuit board 1 consists of a number of circuit board layers (not shown separately) that are arranged one above the other. The circuit board 1 has an upper side 11 and an underside 12.

Electrical modules 2 are arranged on the underside 12 of the circuit board 1. A connection to the circuit board 1 is accomplished, for example, by surface mounting. This is, however, merely an example. In addition, electrical components may also be arranged on the upper side 11 of the circuit board 1. Of interest in the present context are the electrical modules 2 arranged on the underside 12, which are active components (e.g., modules of the power electronics) that require cooling by a heat sink 3. For this purpose, the heat sink 3 has a recess 30, into which the modules 2 to be cooled project. The modules 2 to be cooled come into thermal contact with the heat sink 3 on their underside.

In this case, it is disadvantageous if there is a gap between the respective module 2 and the heat sink 3 since such a gap impairs the thermal connection to the heat sink 3. To improve the thermal connection, a heat-conducting material 6 is arranged between the modules 2 to be cooled and the heat sink 3.

The circuit board 1 is screwed to the heat sink 3 by metal screws 5. The metal screws 3 are screwed into through-holes 15 that extend from the circuit board 1 into the heat sink 3. The metal screws 3 rest on the upper side 11 of the circuit board 1 via a washer 5 and metallization 52. The metal screws 3 provide a pressure force with which the circuit board 1 is pressed against the heat sink 3. For example, the metal screws 3 provide the pressure force with which the electrical modules 12 to be cooled, which are arranged on the underside 12 of the circuit board 1, are pressed against the surface of the heat sink 3 via the heat-conducting material 6 in order to provide a good thermal transition.

The heat sink 3 may have numerous configurations. For example, the heat sink 3 consists of a metal such as, for example, aluminum or an aluminum alloy and has cooling surfaces (not shown separately). The heat sink 3 is, for example, an active heat sink that is actively cooled by a fan (not shown) or by a liquid cooling system (not shown). Alternatively, the heat sink 3 is configured as a passive heat sink.

In alternative embodiments (not shown), provision may be made that, in order to improve the thermal contact between the module 2 to be cooled and the heat sink 3, a hold-down device is additionally used. The hold-down device presses the circuit board 1 against the heat sink 3.

In regions A below the electrical module 2, the heat-conducting material 6 is pressed with a high mechanical pressure against the heat sink 3 on account of the pressure force provided by the screws 5. In regions B between the individual electrical modules 2 or adjacent to the respective electrical module 2, however, the heat-conducting material 2 merely rests thereon. This is indicated (not to scale) in FIG. 3 by arching of the heat-conducting material 2. Accordingly, there is no or only slight mechanical pressure on the heat-conducting material 2 adjacent to the electrical modules 2. Thus, there is only reduced heat transfer from the heat-conducting material 2 into the heat sink 3 in these regions.

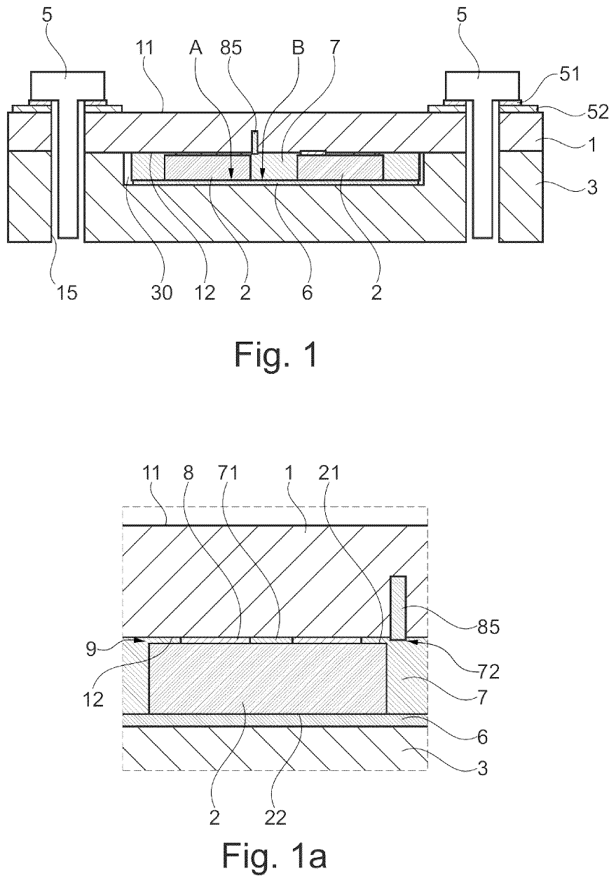

FIG. 1 shows an example of an embodiment of a circuit board arrangement. The basic structure is the same as that explained with reference to FIG. 3, and therefore, reference is additionally made to the explanations relating to FIG. 3. According to FIG. 1, the illustrated electrical modules 2 may be embedded in an encapsulating material 7. In this case, the encapsulating material 7 terminates with the underside of the electrical module 2 without covering the underside. The encapsulating material 7 has the effect that the heat-conducting material 7 is also pressed with a high mechanical pressure against the heat sink 3 in regions B that are adjacent to the electrical modules 2 or lie between the electrical modules 2. A high mechanical pressure is present both in the regions A below the electrical modules 2 and in the regions B between or next to the electrical modules 2.

In this case, the encapsulating material 7 may be configured as a hard encapsulating compound that has a greater hardness than the heat-conducting material. The encapsulating material 7 is an epoxy resin or some other thermosetting plastic, for example. The embedding of the electrical modules 2 in the encapsulating material 7 is accomplished by transfer molding or injection molding, for example, as will be explained with reference to FIGS. 5 to 7.

The heat-conducting material 7 is formed by a heat-conducting film, a heat-conducting mat, or a heat-conducting paste, for example. In this case, provision may be made for an anisotropic heat-conducting film (e.g., a graphite film) to be used, which has a greater thermal conductivity in the plane than in the vertical direction. The use of an anisotropic heat-conducting film makes it possible to spread the heat emanating from the electrical module over the surface. Owing to the high contact pressure according to the present embodiments, even in the regions B, the spread heat may be conducted into the heat sink 3 over the entire heat sink surface. In this context, one embodiment variant provides using a heat-conducting material with a high thermal conductivity in the plane, in the range between 200 W/mK and 1000 W/mK.

As will be explained below with reference to the detail view of FIG. 1a, which shows a subregion of the circuit board arrangement of FIG. 1 in the region of an electrical module 2, the encapsulating material 7 also serves to electrically insulate critical regions between the electrical module 2 and the circuit board 1, and on the circuit board 1.

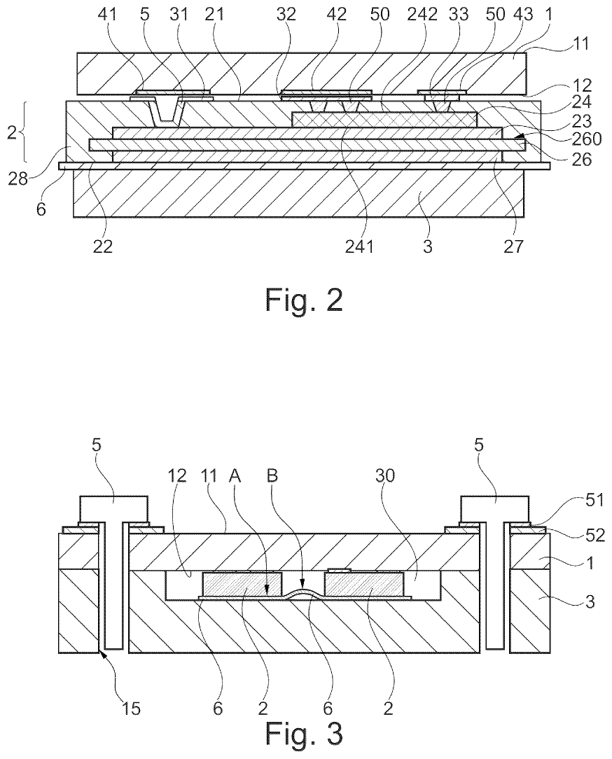

Thus, the encapsulating material 7 also fills a gap 9 that extends between the upper side 21 of the electrical module 2 and the underside 12 of the circuit board 1. In the gap 9, there are electrical contacts 8, via which the electrical module 2 is electrically and mechanically connected to the underside 12 of the circuit board 1. As will be explained with reference to FIG. 2, these electrical contacts 8 may each include a solder pad on the upper side of the electrical module, a solder layer, and a solder pad on the underside of the circuit board.

In the gap 9, in regions 71 adjacent to the electrical contacts 8, the encapsulating material 7 extends between the underside 12 of the circuit board 1 and the upper side 21 of the electrical module 2. In this case, the encapsulating material 7 replaces an underfill material that would have to be introduced into the gap 9 by an underfill process. As a result, the risk of bubble formation in the gap 9 between the electrical module 2 and the circuit board 1 is reduced.

In addition, the encapsulating material 7 also surrounds and insulates a region 72 on the underside 12 of the circuit board 1 in which the circuit board forms vias 85. In this case, FIGS. 1, 1a show schematically, and by way of example, only one such via 85. The vias 85 serve, for example, for the application of high voltage to solder pads on the underside of the circuit board 1.

Attention is drawn to the fact that the illustrated number of two electrical modules 2 in FIG. 1 is to be understood merely as an example. For example, two or more rows of electrical modules may be provided one behind the other (e.g., perpendicularly to the plane of the drawing).

The encapsulating material 7 extends as far as the underside 12 of the circuit board 1, thus substantially completely filling the recess 30 in the heat sink 3 (e.g., apart from possibly edge regions in which the recess 30 is not filled with encapsulating material). The result is that heat emanating from other electrical components (not shown) of the circuit board may also be dissipated into the heat sink 7 via the circuit board 1, the encapsulating material 7, and the heat-conducting material 6.

The underside 22 of the electrical module 2, as well as the lower surface of the encapsulating material 7, presses on the heat-conducting material 6.

The electrical modules 2 of FIG. 1 may be configured in examples of embodiments according to FIG. 2. Accordingly, the electrical module 2 has an upper side 21 and an underside 22. The electrical module 2 includes a ceramic circuit carrier 260, an electrical component 24, and electrical contacts 31, 32, 33 that are arranged on the upper side 21 of the module 2. The ceramic circuit carrier 260 includes an insulating ceramic layer 26, a metallization layer 23 arranged on the upper side of the ceramic layer 26, and a further metallization layer 27 arranged on the underside of the ceramic layer 26. The ceramic layer 26 consists, for example, of aluminum nitride (AlN) or silicon nitride (Si₃N₄). The metallization layers 23, 27 consist of copper, aluminum, silver, or tungsten, for example.

On the metallization layer 23, the electrical component 24 is arranged via a solder layer (not shown separately). The component 24 has an underside 241, with which the component 24 is arranged on the metallization layer 23, and an upper side 242. The upper side 242 and the underside 241 may be metallized (e.g., copper-plated). The electrical component 24 is, for example, a power semiconductor that is configured as a chip.

The ceramic circuit carrier 260 and the electrical component 24 are arranged in a substrate 28 that defines the external dimensions of the electrical module 2. In one embodiment, the substrate 28 is an encapsulating compound, in which the ceramic circuit carrier 260 and the electrical component 24 are embedded. Alternatively, the substrate 28 is a circuit board, for which case the ceramic circuit carrier 260 and the electrical component 24 have been embedded in a circuit board in a circuit board embedding process.

The substrate 28 includes an upper side that also forms the upper side 21 of the module 2. The underside of the substrate 28 extends flush with the lower metallization layer 27, which forms the underside 22 of the module 2. The lower metallization layer 27 of the ceramic circuit carrier 260 is connected via a heat-conducting material 6 to a heat sink 3. Waste heat of the electrical component 24 is dissipated via the heat sink 3.

The electrical contacts 31, 32, 33 on the upper side 21 of the module are provided by solder pads. The solder pads 31, 32, 33 are electrically connected via solder connections to the solder pads 41, 42, 43 of the circuit board 1. For example, a drain terminal is provided via the solder pad 31, and a source terminal and a gate terminal of the electrical component 24 are provided via the solder pads 32, 33.

Starting from the solder pad 31, vias 5 extend to the upper metallization layer 23 of the ceramic circuit carrier 260. Further, vias 50 extend from the solder pads 32, 23 to the upper side 242 of the electrical component 24.

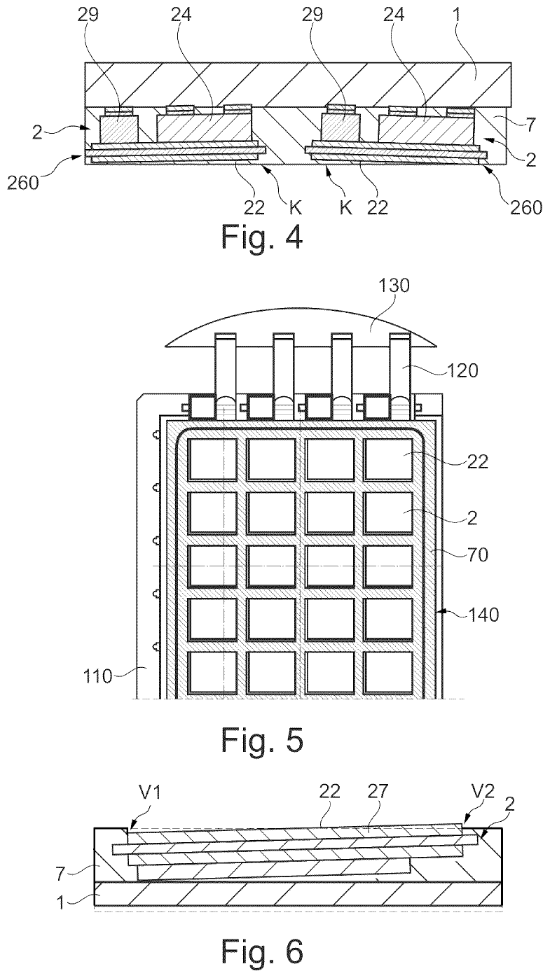

FIG. 4 illustrates possible problems that may arise during the production of a circuit board arrangement according to FIG. 1. Thus, FIG. 4 shows two electrical modules 2 (e.g., each with a ceramic circuit carrier 260, an electrical component 24, and a spacer 29 in a similar structure as that explained with reference to FIG. 2) that are slightly tilted (e.g., by ±50 μm) after being soldered onto the circuit board 1. The tilting may lead to the encapsulating material 7 also covering the underside of the electrical modules 2 in the regions K. However, this should be avoided because this would impair the thermal transition between the electrical module 2 and the heat sink 3.

FIGS. 5-7 explain a method for producing a circuit board arrangement according to FIG. 1, where it is provided that, even in the case of a tilted arrangement of the electrical modules 2 on the underside of the circuit board 1, the encapsulating compound 7 does not cover the underside 22 of the electrical module.

An encapsulating compound is supplied by transfer molding in a mold 110. This includes a mold cavity 140, into which a circuit board with electrical modules 2 arranged thereon may be inserted. A molding compound 70 may be forced into the mold cavity 140 by channels 120 and a press 130.

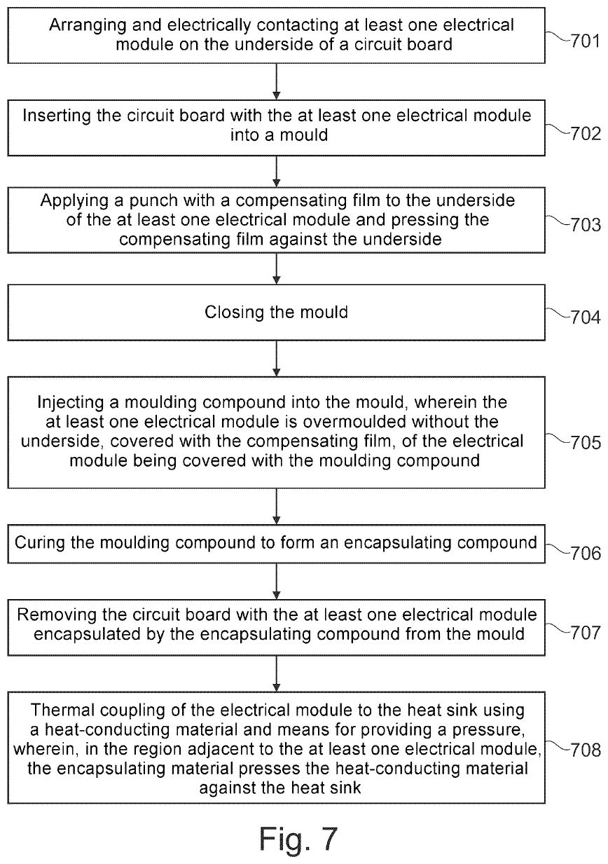

FIG. 7 explains one embodiment of a method. First, in act 701, at least one electrical module or a plurality of electrical modules 2 is arranged on the underside of a circuit board. This is accomplished by a soldering process. Then, in act 702, the circuit board with the electrical modules 2 is inserted into the mold 110 (e.g., into its mold cavity 140). In one embodiment, the underside 22 of the electrical modules in the illustration in FIG. 5 faces upwards. By way of example, 4×5 electrical modules are arranged on the circuit board per panel and inserted into the mold 110.

According to act 703, a punch with a compensating film is then applied to the underside 22 of each of the electrical modules 2, and the compensating film is pressed against the respective underside 22 by the punch. In the illustration in FIG. 5, the punch with the compensating film (not shown separately) is placed on the underside 22 of the respective module 2 from above. The compensating film is, for example, a Teflon film. The mold 110 is then closed in act 704. A molding compound is now injected under pressure into the mold 110 via the channels 120 and left in the mold for a certain time, in act 705. In one embodiment, the volume to be overmolded is precisely defined by the mold 110 and its mold cavity 140. In this case, the electrical modules 2 are overmolded without the underside, which is in each case covered with a compensating film, being covered with the molding compound. The compensating film prevents this even if the modules 2 are arranged in a tilted manner on the circuit board.

During the dwell time of the molding compound in the mold 110, the molding compound is vulcanized or cured to form the encapsulating compound, in act 706. The dwell time depends on various factors, such as the type of resin, any fillers used, processing pressure, and processing temperature. Once the dwell time has ended, the mold 110 is opened, and the circuit board with the electrical modules 2 encapsulated by the encapsulating compound is removed from the mold 110, in act 707.

Subsequently, in act 708, the electrical modules 2 are thermally coupled to a heat sink. This is accomplished using a heat-conducting material and a pressure supplier (e.g., a pressure applicator) corresponding, for example, to the embodiment in FIG. 1. In this case, the encapsulating material presses the heat-conducting material against the heat sink in the region adjacent to the electrical modules 2.

The result of using a punch with a compensating film is illustrated in FIG. 6, which shows a single electrical module 2 that is embedded in an encapsulating compound 7. The electrical module is configured, for example, according to FIG. 2 and includes a ceramic circuit carrier with a metallization layer 27, which forms the underside 22 of the electrical module 2. At the edges of the metallization layer 27, there is in each case a small vertical offset V1, V2 with respect to the surface of the encapsulating material 7, which is, for example, in the range between 0.01 mm and 0.1 mm. Here, the underside 22 of the electrical module 2 is free of encapsulating material 7. The offset is caused by the compensating film, which presses against the underside 22 during transfer molding.

The invention is not restricted to the embodiments described above, and various modifications and improvements may be made without departing from the concepts described herein. Any of the features described may be used separately or in combination with any other features, provided that they are not mutually exclusive. The disclosure extends to and includes all combinations and sub-combinations of one or more features that are described here. If ranges are defined, these ranges therefore include all the values within these ranges, as well as all the partial ranges that lie within a range.

The elements and features recited in the appended claims may be combined in different ways to produce new claims that likewise fall within the scope of the present invention. Thus, whereas the dependent claims appended below depend from only a single independent or dependent claim, it is to be understood that these dependent claims may, alternatively, be made to depend in the alternative from any preceding or following claim, whether independent or dependent. Such new combinations are to be understood as forming a part of the present specification.

While the present invention has been described above by reference to various embodiments, it should be understood that many changes and modifications can be made to the described embodiments. It is therefore intended that the foregoing description be regarded as illustrative rather than limiting, and that it be understood that all equivalents and/or combinations of embodiments are intended to be included in this description.

1. A circuit board arrangement comprising:
a circuit board having an upper side and an underside;
at least one electrical module having an upper side and an underside, the upper side of the at least one electrical module being arranged on the underside of the circuit board;
a heat sink;
means for providing a pressure, with which the underside of the at least one electrical module is pressed against the heat sink; and
a heat-conducting material that is arranged between the underside of the at least one electrical module and the heat sink,
wherein the at least one electrical module is embedded in an encapsulating material that terminates with the underside of the at least one electrical module without covering the underside of the at least one electrical module, and
wherein the encapsulating material is provided and configured to press the heat-conducting material against the heat sink in a region adjacent to the at least one electrical module.

2. The circuit board arrangement of claim 1, wherein the at least one electrical module comprises a plurality of electrical modules that are embedded in the encapsulating material, and
wherein the encapsulating material is provided and configured to press the heat-conducting material against the heat sink in a region between the plurality of electrical modules.

3. The circuit board arrangement of claim 1, wherein the encapsulating material extends as far as the underside of the circuit board, at least in some section or sections.

4. The circuit board arrangement of claim 1, wherein the at least one electrical module has electrical solder pads formed on the upper side of the at least one electrical module,
wherein each of the electrical solder pads is in contact via a solder layer with an associated electrical solder pad of the circuit board, and
wherein in a region adjacent to the electrical solder pads, the encapsulating material extends also in a gap between the underside of the circuit board and the upper side of the at least one electrical module.

5. The circuit board arrangement of claim 1, wherein the encapsulating material surrounds and electrically insulates regions on the underside of the circuit board in which the circuit board forms vias.

6. The circuit board arrangement of claim 1, wherein the encapsulating material has a hardness that is greater than a hardness of the heat-conducting material.

7. The circuit board arrangement of claim 1, wherein the encapsulating material is configured as a hard encapsulating compound.

8. The circuit board arrangement of claim 1, wherein the encapsulating material has a Shore D hardness greater than 10.

9. The circuit board arrangement of claim 1, wherein the encapsulating material is an epoxy resin.

10. The circuit board arrangement of claim 1, wherein the at least one electrical module is embedded in the encapsulating material by transfer molding or injection molding.

11. The circuit board arrangement of claim 1, wherein the heat-conducting material comprises an anisotropic heat-conducting film that has an increased thermal conductivity in the plane.

12. The circuit board arrangement of claim 1, wherein the means for providing a pressure, with which the underside of the at least one electrical module is pressed against the heat sink, comprise screws that extend from the upper side of the circuit board into the heat sink and are screwed into the heat sink.

13. The circuit board arrangement of claim 1, wherein the at least one electrical module comprises:
a ceramic circuit carrier that has an insulating ceramic layer and a first metallization layer arranged on an upper side of the insulating ceramic layer; and
an electrical component that is arranged on an upper side of the first metallization layer and is electrically connected to the upper side of the first metallization layer,
wherein the insulating ceramic layer or a second metallization layer formed on an underside of the insulating ceramic layer is connected to the heat sink via the heat-conducting material.

14. The circuit board arrangement of claim 13, wherein the electrical component is a semiconductor component.

15. The circuit board arrangement of claim 13, wherein electrical contacts of the at least one electrical module comprise at least one first via that extends from a solder pad on the upper side of the at least one electrical module to the first metallization layer, and second and third vias that extend from other solder pads on the upper side of the at least one electrical module to corresponding contacts on the upper side of the electrical component.

16. The circuit board arrangement of claim 1, wherein the at least one electrical module is arranged in a cavity of the heat sink.

17. A method for producing a circuit board arrangement, the method comprising:
arranging and electrically contacting at least one electrical module on an underside of a circuit board;
inserting the circuit board with the at least one electrical module into a mold;
applying a punch with a compensating film to an underside of the at least one electrical module and pressing the compensating film against the underside of the at least one electrical module;
closing the mold;
injecting a molding compound into the mold, wherein the at least one electrical module is overmolded without the underside of the at least one electrical module, covered with the compensating film, of the at least one electrical module being covered with the molding compound,
curing the molding compound, such that an encapsulating compound is formed;
removing the circuit board with the at least one electrical module encapsulated by the encapsulating compound from the mold; and
thermally coupling the at least one electrical module to a heat sink using a heat-conducting material and means for providing a pressure, wherein, in a region adjacent to the at least one electrical module, the encapsulating material is configured to press the heat-conducting material against the heat sink.

18. The method of claim 17, wherein, during the injecting of the molding compound into the mold, the at least one electrical module is overmolded such that the molding compound also closes a gap between the underside of the circuit board and an upper side of the at least one electrical module.

19. The method of claim 17, wherein, during the injecting of the molding compound into the mold, the at least one electrical module is overmolded such that the molding compound also surrounds and electrically insulates regions on the underside of the circuit board in which the circuit board forms vias.

20. The method of claims 17, wherein, in one panel, a plurality of electrical modules are simultaneously overmolded in the mold.
